(19) United States
(12) Patent Application Publication
(10) Pub. No.: US 2011/0318576 A1
(43) Pub. Date: Dec. 29, 2011

(54) METHOD FOR TREATING A SURFACE OF AN ELASTOMER PART USING MULTI-ENERGY IONS HE+ AND HE2+

(75) Inventors: Denis Busardo, Gonneville sur Mer (FR); Frederic Guernalec, Liffre (FR)

(73) Assignee: QUERTECH INGENIERIE, Caen (FR)

(21) Appl. No.: 13/254,705

(22) PCT Filed: Mar. 5, 2010
(86) PCT No.: PCT/FR2010/050379

§ 371 Date: Sep. 2, 2011

(30) Foreign Application Priority Data
Mar. 5, 2009 (FR) 09 01002

(51) Int. Cl. C23C 14/20; B32B 27/06

(52) U.S. Cl. 428/336; 427/525; 427/2.28

(57) ABSTRACT

The invention relates to a method for treating at least one surface of a solid elastomer part using helium ions. According to the invention, multi-energy ions He⁺ and He²⁺ are implanted simultaneously, and the ratio RHe, where RHe=HeVHe²⁺ with He⁺ et He²⁺ expressed in atomic percentage, is less than or equal to 100, for example less than 20, resulting in very significant reductions in the frictional properties of parts treated in this way. The He⁺ and He²⁺ ions are supplied, for example, by an ECR source.

The subject of the invention is a process for treating an elastomer part with multiple-energy He⁺ and He²⁺ ions.

The invention is applicable for example in the biomedical or automotive field, in which it is desired for example to reduce the friction of an elastomer part on a contact surface in order to reduce the resistance forces, abrasive wear or even the noise.

Contact between an elastomer and a rough hard surface takes place by an envelopment of the asperities on the opposing surface. This generates a tangential force which is the result of an adhesive force (due to van der Waals forces) and a deformation force. The deformation force depends on the delay experienced by the elastomer before resuming its initial shape after having followed the asperities of the opposing surface. This delay is called the hysteresis component of the friction and depends on the viscoelastic properties of the elastomer. By increasing the elasticity, this delay time is reduced. The friction force is also the sum of a friction force and a hysteresis force.

The friction coefficient essentially depends on:
the surface composition of the elastomer;
the surface composition of the opposing surface;
the roughness of the opposing surface;
the contact pressure; and
the temperature.

The adhesion is an important effect in the case of elastomers, which corresponds to energies of the order of 100 mJ/m².

Elastomers are defined by their slip G, which is inversely proportional to their friction coefficient μ. The slip is expressed in the following manner:

G=(1/μ)=(1/s)·(m+p)

where s represents the adhesion, m the aptitude of the elastomer to follow the opposing surface and p the contact pressure.

To give an example, the friction coefficient of a natural rubber in static mode varies between 4 and 1.5 for a pressure varying from 0.5 to 3 bar.

In dynamic mode, an increase in the speed produces an adhesion peak in the elastomer on approaching creep speeds and a hysteresis peak at very high speeds.

Elastomers make a particular sound. Under the effect of displacement, appear in the area of contact separation regions between the elastomer and the opposing surface. The surface of the elastomer then undergoes a reptation process, consisting of separation waves propagating in the opposite direction to the friction force. This gives rise to a screaming noise, constituting a real nuisance. To correct this, one approach may consist in reducing the difference that exists between the static friction coefficient and the dynamic friction coefficient. For this purpose, conventional chemical methods of halogenation—fluorination, bromination or even chlorination processes—exist, but these are applicable only to a minority of elastomers. Such processes have great drawbacks: they are very polluting; and they require very large quantities of water to be heated, which then has to be filtered in very expensive reprocessing plants. The effectiveness of these halogenation processes depends greatly on the chemical composition of the elastomer and on its concentration of chemical double bonds capable of undergoing an electrophilic addition. For example, it is very difficult to apply them on an elastomer of the EPDM (ethylene propylene diene monomer) type. In this case, chlorination at very high temperature is recommended.

Apart from friction problems, the elastomer parts must often operate in relatively aggressive chemical environments, with ambient moisture, ambient oxygen, at very low or in contrast very high temperatures, etc., which may result in accelerated ageing.

Certain elastomers are filled with chemical agents for protection against UV or oxidation. The effect of these chemical agents being discharged to the outside is for the elastomer to lose its surface mechanical properties.

Other elastomers, very good from a mechanical standpoint, are however excluded from any medical or pharmaceutical usage because of a minimal risk of toxic discharges—in fact precluding excellent elastomers.

Certain elastomers are insulating and can collect dust, which is retained thereon or even bonded thereto because of electrostatic charges that have built up on their surface during the manufacturing process.

Certain elastomers require the use of talc to avoid parts sticking to one another during the manufacturing process or during assembly.

The object of the invention is to reduce the aforementioned drawbacks and in particular to enable the surface friction of a bulk elastomer part to be reduced, while still keeping its viscoelastic properties in the bulk and avoiding the use of polluting chemical treatments. The invention thus provides a process for treating at least one surface of a bulk elastomer part by helium ions, characterized in that multiple-energy He⁺ and He²⁺ ions are implanted simultaneously, in which the ratio R_{He}, where R_{He}=He⁺/He²⁺ with He⁺ and He²⁺ being expressed in at %, is less than or equal to 100, for example less than 20.

The inventors have found that the simultaneous presence of He⁺ and He²⁺ ions enables the surface properties of elastomers to be very significantly improved compared with the known treatments in which only He⁺ or He²⁺ ions are implanted. They have demonstrated that a significant improvement was obtained for an R_{He} equal to or less than 100, for example equal to or less than 20.

It should be noted that the invention makes it possible to reduce the adhesion of a bulk elastomer part on an opposing surface and/or to reduce the surface hysteresis component of a bulk elastomer part and/or to reduce the abrasive wear of a bulk elastomer part and/or to reduce the sticking between parts made of the same elastomer and/or to eliminate the bonding of dust.

The invention also makes it possible to increase the chemical resistance of the elastomer, for example by creating a permeation barrier. This barrier can slow down the propagation of ambient oxygen into the elastomer and/or retard the diffusion of chemical protection agents contained in the elastomer to the outside and/or inhibit the leaching of toxic agents contained in the elastomer to the outside.

Advantageously, the invention makes it possible to dispense with the current polluting processes, such as fluorination, bromination, chlorination, and to replace them with a physical process which is applicable to any type of elastomer and is not costly in terms of material and energy consumption.

In the context of the present invention, the term “bulk” is understood to mean an elastomer part produced by mechanical or physical conversion of a mass of material, for example by extrusion, molding or any other technique suitable for converting a mass of elastomer. Such conversion operations are used to obtain variously shaped bulk parts, for example three-dimensional parts, substantially two-dimensional parts, such as for example profiled strips or sheets, and substantially unidirectional parts, such as threads.

Among elastomer products that may advantageously be treated by the process of the present invention, the following examples may be mentioned: bodywork seals; hydraulic cylinder scraper seals; O-ring seals; lipped seals; ball joint seals; windshield wiper blades; aircraft wing leading edges; nacelle leading edges; and hypodermic syringe piston heads.

Moreover, it goes without saying that the bulk elastomer part may be a portion of a part made of another material, for example attached to this part made of another material.

As examples and among elastomers, the following materials that benefit from treatment according to the invention may be mentioned:
natural rubbers, which exhibit good wear, tear and abrasion resistance and have a high elongation at break;
nitrile rubbers, which make it possible for example to obtain seals resistant to hot water, steam, weak acids, alkalis and saline solutions;
polychloroprenes (for example those with the brand name Neoprene® from the company DuPont de Nemours) which exhibit excellent resistance to abrasion, oils, gasolines, greases, solvents, ozone and many chemicals and have good elastic recovery after having been kept under a load;
ethylene-propylene elastomers of the EPM or EPDM type (for example the brand name Nordel® from the company DuPont de Nemours or Vistalon® from the company Esso-Chimie) which are particularly resistant to ozone, acids and alkalis, detergents and glycols and remain flexible at very low temperature (−65° C.);
acrylic elastomers (for example the brand name Hycar® from the company Goodrich) which can be used from −40° C. to 200° C., have good compressive strength and withstand the following well; oil-based lubricants; petroleum; greases; hydraulic fluids; oxidizing agents; ozone; diesel;
ethylene-acrylic elastomers (for example the brand name Vamac® from the company DuPont de Nemours) which withstand high temperatures very well and low temperatures quite well and may also constitute good vibration dampers; they also have good tear strength and high levels of elongation. Moreover, they are resistant to hot oils, to hydrocarbon-based and glycol-based lubricants, and transmission fluids;
fluorinated elastomers (for example the brand name Viton® from the company DuPont de Nemours) which have excellent oil and chemical resistance, even at high temperatures. This family of elastomers includes in particular the fluorocarbon rubbers called FKMs;
FEP (fluorinated ethylene propylene) elastomers which have properties similar to fluorinated elastomers and have very good wear resistance;
perfluorinated elastomers (for example the brand name Kalrez® from the company DuPont de Nemours) which have a chemical resistance similar to that of PTFE and the operating temperature limit of which is more than 300° C.;
polyester elastomers (for example the brand name Hytrel® from the company DuPont de Nemours) which are used for applications requiring great toughness and exceptional resistance to flexural fatigue. Their friction coefficient on steel is quite high;
the polyurethane elastomers (for example the brand name Adiprene® from the company DuPont de Nemours) which are characterized by a very high wear and abrasion resistance and high tensile strength; they are very suitable for seals in translational movements (scraper seals) and where high hardness is associated with a low friction coefficient; and
silicone elastomers, which are for example used as static seals from −70° C. to 220° C. and are resistant to hot motor oil, to diesel, to gasoline and to coolants.

According to one embodiment, the He⁺ and He²⁺ ions are produced simultaneously by an electron cyclotron resonance (ECR) ion source.

Using the process of the present invention, it is possible to preserve the original colour of the elastomer, giving it however a glossier appearance.

It is found that the treatment times are not long in relation to industrial requirements.

Furthermore, the process has a low energy requirement, is inexpensive and can be used in an industrial context without any environmental impact.

The treatment of an elastomer part is carried out by simultaneously implanting multiple-energy helium ions. These are in particular obtained by extracting, with one and the same extraction voltage, singly charged or multiply charged ions created in the plasma chamber of an electron cyclotron resonance (ECR) ion source. Each ion produced by said source has an energy proportional to its charge state. It therefore follows that the ions with the highest charge state, and therefore the highest energy, are implanted into the elastomer part at greater depths.

Implantation using an ECR source is rapid and inexpensive since it does not require a high ion source extraction voltage. Indeed, to increase the implantation energy of an ion it is economically preferable to increase its charge state rather than increase its extraction voltage.

It should be noted that the use of a conventional source of He ions, such as in particular the sources for implanting ions by plasma immersion or filament implanters, does not make it possible to obtain a beam suitable for simultaneously implanting multiple-energy He⁺ and He²⁺ ions in which the R_{He} ratio is equal to or less than 100. With such sources, said ratio is at the very most less than or equal to 1000.

The inventors have found that this process enables an elastomer part to be surface-treated without impairing the bulk viscoelastic properties thereof.

According to one embodiment of the present invention, the source is an electron cyclotron resonance source producing multiple-energy ions that are implanted in the part at a temperature below 50° C. and the implantation of the ions of the implantation beam is carried out simultaneously at a controlled depth by the extraction voltage of the source.

Without wishing to be tied by any scientific theory, it is thought that, in the process according to the invention, the ions during their transit excite the electrons of the elastomer, causing a scission of covalent bonds, which immediately recombine to generate, by a crosslinking mechanism, a high density of covalent chemical bonds. This densification of covalent bonds has the effect of increasing, on the surface, the hardness, elasticity and compactness of the elastomer and of increasing its chemical resistance. The crosslinking process is more effective the lighter the ion.

In this regard, helium is an advantageous projectile since:
it is very quick with covalently bonded electrons and therefore very effective for exciting these same electrons, which therefore do not have the time to modify their orbitals;
it penetrates down to large depths, of the order of 1 micron;
it interferes little with the hydrogen atoms of the elastomer;
it is not dangerous; and
being a noble gas, it does not modify the physico-chemical properties of the elastomer.

According to various embodiments of the process of the present invention, which may be combined together:
the ratio R_{He}, where R_{He}=He⁺/He²⁺ with He⁺ and He²⁺ expressed in at %, is greater than or equal to 1;
the extraction voltage of the source for implanting the multiple-energy He⁺ and He²⁺ ions is between 10 and 400 kV, for example equal to or greater than 20 kV and/or less than or equal to 100 kV;
the multiple-energy He⁺ and He²⁺ ion dose is between 5×10¹⁴ and 10¹⁸ ions/cm², for example equal to or greater than 10¹⁵ ions/cm² and/or less than or equal to 10¹⁷ ions/cm², or even equal to or greater than 3×10¹⁵ ions/cm² and/or less than or equal to 10¹⁶ ions/cm²;
the prior step is carried out to determine the variation of a property characteristic of the behavior of the surface of a bulk elastomer part, for example the surface elastic modulus E, the surface hardness or the friction coefficient of an elastomer material representative of that of the part to be treated as a function of the multiple-energy He⁺ and He²⁺ ion doses so as to determine a range of ion doses in which the variation of the characteristic property chosen is advantageous and varies in a differentiated manner in three consecutive regions of ion doses forming said ion dose range with a substantially linear variation in each of these three regions and in which the absolute value of the slope of the variation in the first region and that in the third region are greater than the absolute value of the slope of the variation in the second region and in which the multiple-energy He⁺ and He²⁺ ion dose is chosen in the third ion dose region in order to treat the bulk elastomer part;
the parameters of the source and those of the displacement of the surface of the elastomer part to be treated are regulated so that the rate of treatment per unit area of the surface of the elastomer part to be treated is between 0.5 cm²/s and 1000 cm²/s, for example equal to or greater than 1 cm²/s and/or less than or equal to 100 cm²/s;
the parameters of the source and those of the displacement of the surface of the elastomer part to be treated are regulated so that the implanted helium dose is between 5×10¹⁴ and 10¹⁸ ions/cm², for example equal to or greater than 10¹⁵ ions/cm² and/or less than or equal to 5×10¹⁷ ions/cm²;
the parameters of the source and those of the displacement of the surface of the elastomer part to be treated are regulated so that the depth of helium penetration on the surface of the elastomer part treated is between 0.05 and 3 μm, for example equal to or greater than 0.1 μm and/or less than or equal to 2 μm;
the parameters of the source and those of the displacement of the surface of the elastomer part to be treated are regulated so that the temperature of the surface of the elastomer part during treatment does not exceed 100° C., for example does not exceed 50° C.;
the elastomer part is for example a profiled strip and said part runs through a treatment device, for example at a speed of between 5 m/min and 100 m/min; as an example, the elastomer part is a profiled strip that runs longitudinally;
the helium implantation into the surface of the part to be treated is carried out using a plurality of multiple-energy He⁺ and He²⁺ ion beams produced by a plurality of ion sources. As an example, the ion sources are placed along the direction of displacement of the part to be treated. Preferably, the sources are spaced apart so that the distance between two ion beams is sufficient to allow the part to cool down between each successive ion implantation. Said sources produce ion beams with a diameter matched to the width of the tracks to be treated. By reducing the diameter of the beams, for example to 5 mm, it is possible to provide a very effective differential vacuum system between the source and the treatment chamber, enabling elastomers to be treated at 10⁻² mbar whereas the vacuum in the extraction system of the source is 10⁻⁶ mbar;
the elastomer of the part is chosen from natural rubbers, synthetic rubbers such as polychlorophenes, or semi-synthetic compounds of these two types of elastomer. Other types of elastomer are conceivable, depending on the generic character of the crosslinking process.

It has been found that the teaching obtained on a non-elastomer polymer, for example on a polycarbonate, relating to the variations in surface property obtained by implantation of He⁺ and/or He²⁺ ions cannot be transposed to the present observations and advantages obtained on elastomers treated according to the process of the invention.

The invention also relates to a part where the depth where the helium is implanted is equal to or greater than 50 nm, for example equal to or greater than 200 nm, and the surface elastic modulus E of which is equal to or greater than 15 MPa, for example equal to or greater than 20 MPa, or even equal to or greater than 25 MPa.

The invention also relates to the use of the above treatment process for treating a bulk elastomer part chosen from the list consisting of a windshield wiper blade, a bodywork seal, an O-ring seal, a lipped seal, a hydraulic cylinder scraper seal, a ball joint seal, an aircraft wing leading edge, an aircraft jet engine nacelle leading edge, a hypodermic syringe piston, or an automobile liner for damping vibrations between contacting parts.

The present invention will now be illustrated by examples of nonlimiting embodiments, especially with reference to the appended drawings in which:

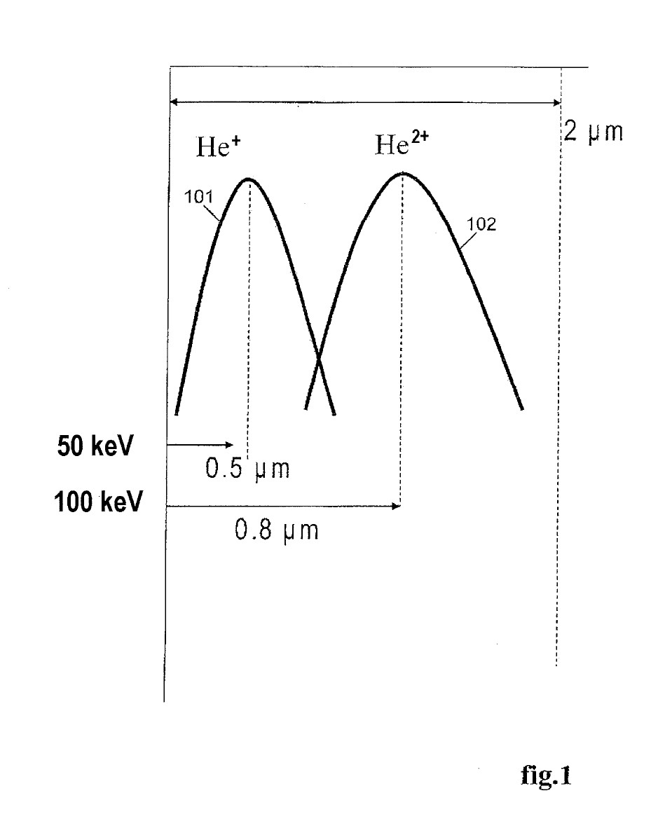

FIG. 1 shows an example of a distribution of helium implantation according to the invention in a natural rubber;

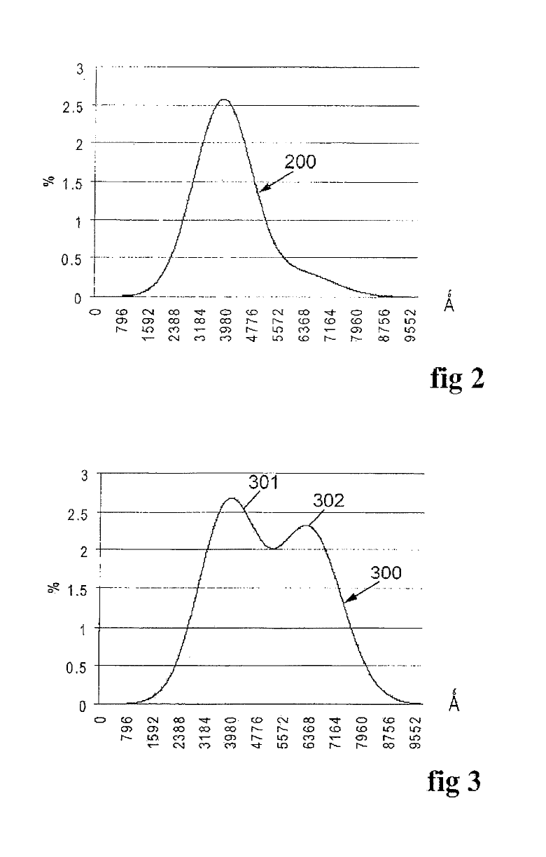

FIGS. 2 and 3 show two examples of an implantation profile illustrating the variation in the concentration of helium atoms implanted in a natural rubber treated according to the invention;

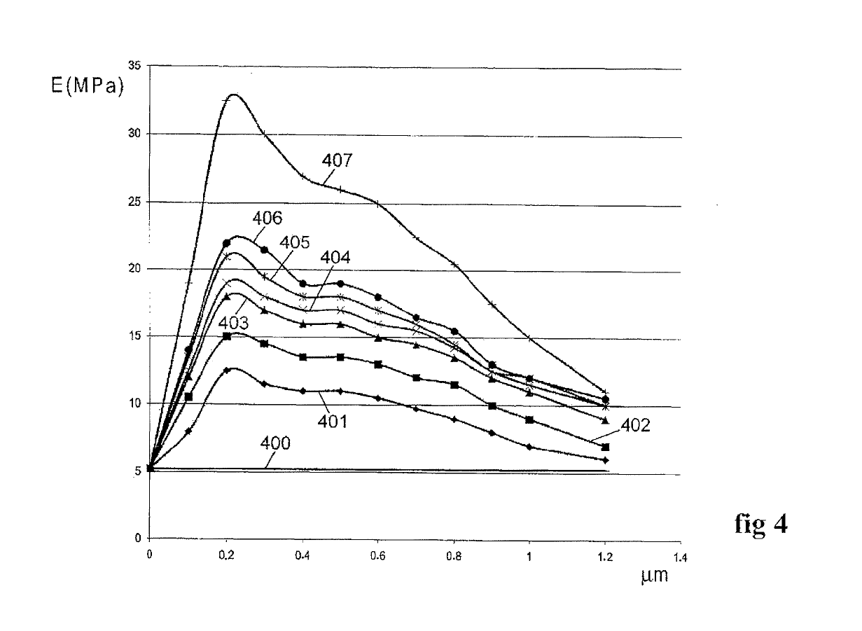

FIG. 4 shows the variation of the surface elastic modulus of a natural rubber specimen treated according to the invention as a function of the depth for a number of helium doses; and

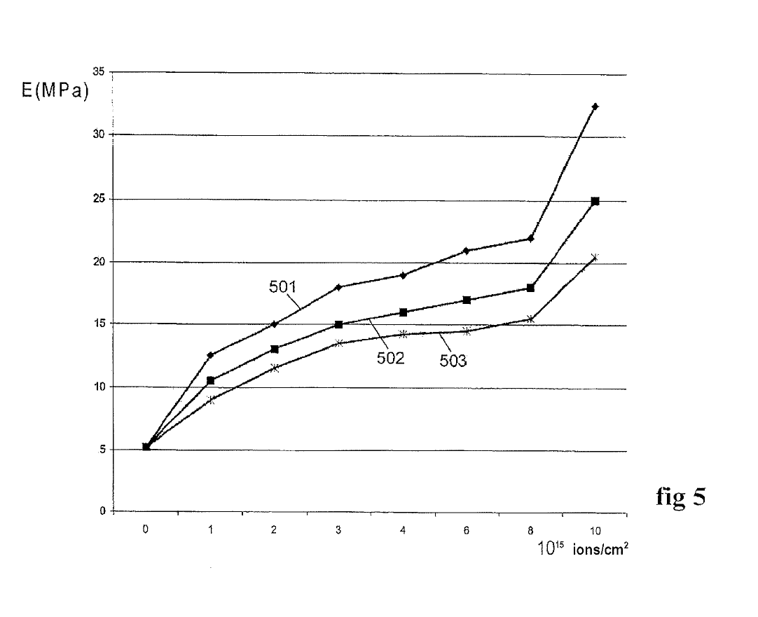

FIG. 5 shows the variation of the surface elastic modulus of a natural rubber specimen treated according to the invention as a function of the helium dose for three depths.

FIG. 1 shows a schematic example of the distribution of helium implantation as a function of the depth according to the invention in a natural rubber. Curve 101 corresponds to the He⁺ distribution and curve 102 to the He²⁺ distribution. It may be estimated that the He²⁺ ions with an energy of 100 keV travel an average distance of about 800 nm for an average ionization energy of 10 eV/ångström. For 50 keV energies, He²⁺ ions travel an average distance of about 500 nm for an average ionization energy of 4 ev/ångström. The ionization energy of an ion is proportional to its crosslinking power. In the case in which (He⁺/He²⁺) is equal to or less than 100, the maximum treated depth may be estimated to be around 1000 nm, i.e. 1 micron. These estimates are consistent with electron microscopy observations that have demonstrated that a crosslinked layer of about 700 to 800 nm is observed for a beam extracted at 40 kV and for a total dose of 3×10¹⁵ ions/cm² and (He⁺/He²⁺)=10.

FIG. 2 shows an example of an implantation profile 200 illustrating the helium atom concentration implanted in natural rubber (expressed in %) as a function of the implantation depth (expressed in ångströms). In this example, the dose is 3×10¹⁶ ions/cm² and (He⁺/He²⁺)=10 for He⁺ ions at 50 keV and He²⁺ ions at 100 keV. This shows that the helium (He⁺ and He²⁺) concentration is very small compared with the atomic components of rubber, since this concentration is around 2%. This shows that the maximum implanted He dose is at about 0.4 μm in depth and that a significant amount of He is implanted down to about 0.8 μm.

FIG. 3 shows an example of an implantation profile 300 illustrating the atomic concentration of implanted helium in natural rubber (expressed in %) as a function of the implantation depth (expressed in ångströms). In this example, the dose is 5×10¹⁶ ions/cm² and (He⁺/He²⁺)=1 with He⁺ at 50 keV and He²⁺ at 100 keV. It may be seen that there are two peaks 301, 302 which mark depths where the He implantation is a maximum and correspond to maximum implantation of He⁺ and He²⁺ respectively.

Several methods of characterization have enabled the advantages of the present invention to be established.

In the following examples, the treatment of at least one surface of a bulk elastomer part by implanting He⁺ and He²⁺ helium ions was carried out with multiple-energy He⁺ and He²⁺ ions produced simultaneously by an ECR source. The treated elastomers were in particular the following: natural rubber (NR), polychloroprene (CR), ethylene propylene diene monomer (EPDM), fluorocarbon rubber (FKM), nitrile rubber (NBR), thermoplastic elastomer (TPE). In all cases, a very significant reduction in the friction coefficient against a glass surface was found.

Comparative tests relating to the measurement of friction coefficient have demonstrated that:
the friction coefficient on a glass surface is greatly reduced. After treatment with 90% He⁺ at 40 keV and 10% He²⁺ at 90 keV for a total dose of 3×10¹⁵ ions/cm², the friction coefficients given below, compared with those obtained before treatment, were measured:

| Type of elastomer | Before treatment | After treatment |
|---|---|---|
| Natural rubber (NR) | 2.35 | 0.35 |
| Polychloroprene (CR) | 2.4 | 0.31 |
| Ethylene propylene diene | 2.1 | 0.46 |
| monomer (EPDM) | | |
| Fluorocarbon rubber (FKM) | 4.5 | 0.6 |

the friction coefficient on a glass surface having various surface states (dry, wet, drying phase) is greatly reduced whatever the surface state of the glass. As an example for an EPDM elastomer treated with 90% He⁺ at 40 keV and 10% He²⁺ at 90 keV for a total dose of 2×10¹⁵ ions/cm², the friction coefficients given below were measured:

| Surface state | Friction coefficient |
|---|---|
| of the glass | after treatment |
| Dry | 0.54 |
| Wet | 0.68 |
| Drying phase | 0.52 |

moreover, the power of the noise source produced by the friction was found to be reduced by a factor of at least 2.

Moreover, other beneficial surface properties may be found:
surface resistivity measurements were carried out according to the IEC 60093 standard on a sheet of natural rubber treated with (90%) He⁺ at 40 keV and 10% He²⁺ at 90 keV for a total dose of 3×10¹⁵ ions/cm². These tests revealed a reduction in the surface resistivity after treatment by a factor of 5.2. The resistivity of the natural rubber treated was 1.1 Mohms/square, the resistivity of untreated natural rubber being 5.9 Mohms/square. This reduction in surface resistivity results in the increase in antistatic properties so as to avoid bonding of dust as had been observed; and
the elastomer part after treatment according to the invention took on a shiny appearance, interpreted as an improvement in the surface conductivity of the material as a result of the creation of carbon double bonds allowing delocalized electron flow. The conducting surfaces are by nature reflective. A relationship may be established between the shiny relative area (% area that reflects light under identical exposure conditions) and the dose received by the elastomer, expressed in ions/cm². This relationship is substantially linear for ion doses up to a limiting dose. Above this limit, saturation occurs and the increase in the total ion dose no longer has an influence on the relative proportion of shiny area. This relationship may be advantageously used to control the quality of the treatment carried out on an elastomer part. The method consists in taking a digital photograph of a virgin part and digital photographs of a part treated with various doses (expressed in ions/cm²) under the same exposure conditions (light source, position of the part beneath the light source, angles at which the photographs are taken). Each digital photograph was converted to black and white. Each pixel of the photograph takes a gray value between 0 and 256 bits. A gray level threshold is then set, below which the pixel is black and above which the pixel is white. Finally, the shiny area of the part is calculated by collecting the white pixels and the dark area of the part by collecting the black pixels. The relative shiny area expressed in percent corresponds to the (white pixel area)/(white pixel area+black pixel area) ratio. This quality control method is simple, inexpensive and very rapid, and may be easily applied on a continuous treatment line. As an example, the table below gives the results relating to the variation in relative shiny area (expressed in percent) as a function of the received dose (expressed in ions/cm²) for a windshield wiper blade made of natural rubber treated with a beam consisting of 90% He⁺ at 40 keV and 10% of He²⁺ at 90 keV. The blade was exposed to vertical light with an angle of incidence of 45°. The photographs were taken along the horizontal reflection axis.

| | Dose | | | | | | | |
|---|---|---|---|---|---|---|---|---|
| | 0 | 10¹⁵ | 2 × 10¹⁵ | 3 × 10¹⁵ | 4 × 10¹⁵ | 5 × 10¹⁵ | 6 × 10¹⁵ | 7 × 10¹⁵ |
| Relative | 14 | 27 | 37 | 42 | 41 | 43 | 40 | 41 |
| shiny area % | | | | | | | | |

The relative shiny area represents only 14% of the area of the untreated blade (before treatment according to the invention). The shiny area increases linearly up to 41% for a dose of 3×10¹⁵ ions/cm². Above this, a saturation plateau is observed, the relative shiny area no longer varying but remaining equal to 42% of the area of the blade.

According to one embodiment, it is estimated that the surface properties of an elastomer, especially the friction properties, are significantly improved using a dose of 10¹⁵ ions/cm², which represents a treatment rate of about 30 cm²/s for a helium beam consisting of 4.5 mA of He⁺ ions and 0.5 mA of He²⁺ ions.

The simultaneous implantation of helium ions may take place at variable depths, depending on the requirements and the shape of the part to be treated. These depths depend in particular on the implantation energies of the ions of the implantation beam. For example, they may vary from 0.1 to about 3 μm for an elastomer. For applications in which the mechanical stresses are high, such as those relating to bodywork seals rubbing on a glass pane, treatment depths of around 1 micron will for example be used. For applications in which for example anti-sticking properties are desired, a depth of less than one micron may for example be sufficient, thereby reducing the treatment time accordingly.

According to one embodiment, the He⁺ and He²⁺ ion implantation conditions are chosen so that the elastomer part retains its bulk viscoelastic properties due to keeping the part at treatment temperatures below 50° C. This result may especially be achieved for a beam of 4 mm diameter delivering a total current of 60 microamps with an extraction voltage of 40 kV, which is moved at 40 mm/s over displacement amplitudes of 100 mm. This beam has a power per unit area of 20 W/cm². To use beams of higher current with the same extraction voltage and the same power per unit area, and to maintain the bulk viscoelastic properties, a scale rule may be suggested that consists of increasing the diameter of the beam, of increasing the rate of displacement and of increasing the amplitudes of displacement in a ratio corresponding to the square root of (desired current/60 microamps). For example for a current of 6 milliamps (i.e. 100 times 60 microamps), the beam may have a diameter of 40 mm in order to maintain a surface power of 20 W/cm². It is necessary under these conditions to increase the speed by a factor of 10 and the amplitudes of displacement by a factor of 10, thereby giving a speed of 40 cm/s and displacement amplitudes of 1 m. The number of passes should also be increased by this same factor in order in the end to have the same treatment dose expressed in ions/cm². In the case of the continuously running treatment, the number of micro accelerators placed for example along the path of a strip may be increased in the same ratio.

It has also been found that other surface properties are very significantly improved by virtue of a treatment according to the invention and that performance levels apparently unable to be achieved with other techniques have been demonstrated.

FIGS. 4 and 5 show the variation of the surface elastic modulus of a natural rubber specimen treated according to the invention with a beam of He ions obtained by an ECR source, comprising 90% He⁺ (at 40 keV) and 10% HE²⁺ (at 80 keV).

The surface elastic modulus may be measured in particular using an instrumented nano indentation technique. This technique is used for mechanically characterizing the surfaces of materials at depths of the order of a few tenths to a few tens of nanometers. The principle consists in applying a load, via an indenter, on a surface. The instrument measures the penetration and quantities (stiffness, phase, etc.) corresponding to the response of the material to the stress. The surface elastic modulus may thus be measured as a function of the depth. In the case of an elastomer material, loading is followed by unloading, which has a reversible character in which the unloading behavior as a function of time is analyzed so as to determine the viscoelastic properties of the material and to deduce the surface elastic modulus. The measurement may be carried out statically or dynamically.

The following publications serve to illustrate metrological methods of this type so as to determine the surface elastic modulus of an elastomer:
J. L. Loubet, J. M. Georges, O. Marchesini et al. “Vickers indentation Curves of Magnesium Oxide (MgO)”, Journal of Tribology, 1984, Vol. 106 pages 43-48;
J. L. Loubet, M. Bauer, A. Tonck et al. “Nanoindentation with a surface force apparatus: Mechanical properties and deformation of materials having ultra-fine microstructures”, K. A. Press, 1993;
J. B. Pethica, R. Hutchings and W. C. Oliver, Philosophical Magazine, 1983, Vol. A48(4), pages 593-606;
B. N. Lucas, W. C. Oliver, G. M. Pharr et al. “Time dependent deformation during indentation testing” Materials Research Society Symposia Proceedings, 1997, Vol. 436, pages 233-238; and
B. J. Briscoe, L. Fiori and E. Pelillo “Nano-indentation of polymeric surfaces”, Journal of Physics Part D: Applied Physics, 1998, Vol. 31, pages 2395-2405.

In FIG. 4, the measured values of the surface elastic modulus (expressed in MPa) are plotted as a function of the depth (expressed in μm) on the external surface treated for various He ion doses, in which the plotted curves correspond to the ion doses given in the table below:

| Curve | He ion dose |
|---|---|
| 400 | Control specimen (0 ions/cm²) |
| 401 | 1 × 10¹⁵ ions/cm² |
| 402 | 2 × 10¹⁵ ions/cm² |
| 403 | 3 × 10¹⁵ ions/cm² |
| 404 | 4 × 10¹⁵ ions/cm² |
| 405 | 6 × 10¹⁵ ions/cm² |
| 406 | 8 × 10¹⁵ ions/cm² |
| 407 | 10 × 10¹⁵ ions/cm² |

In FIG. 5, the measured values of the surface elastic modulus are plotted as a function of the He ion dose (expressed in 10¹⁵ ions/cm²) in which plotted curves 501, 502 and 503 correspond to a measurement at a depth of 0.2, 0.6 and 0.8 μm respectively.

It may be seen that elastomer parts having a surface modulus E equal to or greater than 15 MPa, for example equal to or greater than 20 MPa or even equal to or greater than 25 MPa, may be obtained. These surface elastic modulus values are remarkable and have not been found for elastomers. Surprisingly, it may be seen that the surface elastic modulus E varies differently in three consecutive He ion dose ranges with a substantially linear behavior in each of these three regions: from 0 to about 3×10¹⁵ ions/cm², the surface elastic modulus increases very substantially; on about 3×10¹⁵ ions/cm² to about 8×10¹⁵ ions/cm², the surface elastic modulus increases more slowly; and it increases more rapidly above about 8×10¹⁵ ions/cm². This observation is noteworthy as it is commonly accepted that ion implantation can make it possible to improve a property characteristic of the behavior of the surface of an organic material but that this improvement reaches a plateau after which there is in general a degradation in said property when the implanted ion dose increases.

In the present case, it may be seen that above a second region, lying between about 3×10¹⁵ ions/cm² and about 8×10¹⁵ ions/cm², which may be termed the plateau region, a property characteristic of the behavior of the surface of an elastomer may be greatly improved.

According to one embodiment, when it is desired to improve a surface property of an elastomer very significantly, an ion dose range is determined in which the variation of the chosen characteristic property is advantageous and behaves differently in three consecutive ion dose regions forming said ion dose range, with a substantially linear behavior in each of these three regions and in which the absolute value of the slope of the variation in the first region and that of the third region are greater than the absolute value of the slope of the variation in the second region, and in which the multiple-energy dose of He⁺ and He²⁺ ions is chosen to be in the third ion dose region in order to treat the bulk elastomer part.

The invention is not limited to these types of embodiment and must be interpreted non-limitingly, as encompassing the treatment of any type of elastomer.

Likewise, the process according to the invention is not limited to the use of an ECR source, and even though it might be thought that other sources would be less advantageous, the process according to the invention may be implemented with mono-ion sources or with other multiple-ion sources provided that these sources are configured so as to allow simultaneous implantation of multiple-energy He⁺ and He²⁺ ions.

1. A process for treating at least one surface of a bulk elastomer part by helium ions, characterized in that multiple-energy He⁺ and He²⁺ ions are implanted simultaneously, in which the ratio R_{He}, where R_{He}=He⁺/He²⁺ with He⁺ and He²⁺ being expressed in at %, is less than or equal to 100, for example less than 20.

2. The treatment process as claimed in claim 1, characterized in that the He⁺ and He²⁺ ions are produced simultaneously by an electron cyclotron resonance (ECR) ion source.

3. The treatment process as claimed in claim 1, characterized in that the ratio R_{He} is greater than or equal to 1.

4. The treatment process as claimed in claim 1, characterized in that the extraction voltage of the source for implanting the multiple-energy He⁺ and He²⁺ ions is between 10 and 400 kV, for example equal to or greater than 20 kV and/or less than or equal to 100 kV.

5. The treatment process as claimed in claim 1, characterized in that the multiple-energy He⁺ and He²⁺ ion dose is between 5.10¹⁴ and 10¹⁸ ions/cm², for example equal to or greater than 10¹⁵ ions/cm² and/or less than or equal to 10¹⁷ ions/cm², or even equal to or greater than 3×10¹⁵ ions/cm² and/or less than or equal to 10¹⁶ ions/cm².

6. The treatment process as claimed in claim 1, characterized in that the prior step is carried out to determine the variation of a property characteristic of the behavior of the surface of a bulk elastomer part, for example the surface elastic modulus E, the surface hardness or the friction coefficient of an elastomer material representative of that of the part to be treated as a function of the multiple-energy He⁺ and He²⁺ ion doses so as to determine a range of ion doses in which the variation of the characteristic property chosen is advantageous and varies in a differentiated manner in three consecutive regions of ion doses forming said ion dose range with a substantially linear variation in each of these three regions and in which the absolute value of the slope of the variation in the first region and that in the third region are greater than the absolute value of the slope of the variation in the second region and in which the multiple-energy He⁺ and He²⁺ ion dose is chosen in the third ion dose region in order to treat the bulk elastomer part.

7. The treatment process as claimed in claim 1, characterized in that the parameters of the source and those of the displacement of the surface of the elastomer part to be treated are regulated so that the rate of treatment per unit area of the surface of the polymer or elastomer part to be treated is between 0.5 cm²/s and 1000 cm²/s, for example equal to or greater than 1 cm²/s and/or less than or equal to 100 cm²/s.

8. The treatment process as claimed in claim 1, characterized in that the parameters of the source and those of the displacement of the surface of the elastomer part to be treated are regulated so that the implanted helium dose is between 5×10¹⁴ and 10¹⁸ ions/cm², for example equal to or greater than 10¹⁵ ions/cm² and/or less than or equal to 5.10¹⁷ ions/cm².

9. The treatment process as claimed in claim 1, characterized in that the parameters of the source and those of the displacement of the surface of the elastomer part to be treated are regulated so that the depth of helium penetration on the surface of the elastomer part treated is between 0.05 and 3 μm, for example equal to or greater than 0.1 μm and/or less than or equal to 2 μm.

10. The treatment process as claimed in claim 1, characterized in that the parameters of the source and those of the displacement of the surface of the elastomer part to be treated are regulated so that the temperature of the surface of the elastomer part during treatment does not exceed 100° C., for example does not exceed 50° C.

11. The treatment process as claimed in claim 1, characterized in that the elastomer part to be treated is an automobile part, for example an extruded strip, and in that said part runs through a treatment device, for example at a speed of between 5 m/min and 100 m/min.

12. The treatment process as claimed in claim 1, characterized in that the helium implantation into the elastomer surface of the part to be treated is carried out using a plurality of multiple-energy He⁺ and He²⁺ ion beams produced by a plurality of ion sources.

13. The treatment process as claimed in claim 1, characterized in that the elastomer of the part is chosen from natural rubbers, nitrile rubbers, polychloroprenes, compounds of natural and synthetic rubbers, ethylene-propylene elastomers, acrylic elastomers, ethylene-acrylic elastomers, fluorinated elastomers, fluorinated ethylene-propylene elastomers, perfluorinated elastomers, polyester elastomers, polyurethane elastomers and silicone-based elastomers.

14. An elastomer part having at least one helium-implanted surface, characterized in that the thickness where the helium is implanted is equal to or greater than 50 nm, for example equal to or greater than 200 nm, and the surface elastic modulus E of which is equal to or greater than 15 MPa, for example equal to or greater than 20 MPa, or even equal to or greater than 25 MPa.

15. The use of the treatment process as claimed in claim 1, for treating a bulk elastomer part chosen from the list consisting of a windshield wiper blade, a bodywork seal, a hydraulic cylinder scraper seal, an O-ring seal, a lipped seal, a jet engine nacelle leading edge, an aircraft wing leading edge, a hypodermic syringe piston, an automobile vibration-damping liner or a ball joint seal.
